(19) United States
(12) Patent Application Publication
(10) Pub. No.: US 2025/0258226 A1
(43) Pub. Date: Aug. 14, 2025

(54) MOVING MAX ENVELOPE FILTER

(71) Applicant: Tektronix, Inc., Beaverton, OR (US)

(72) Inventor: Kevin C. Spisak, Beaverton, OR (US)

(21) Appl. No.: 19/051,124

(22) Filed: Feb. 11, 2025

Related U.S. Application Data
(60) Provisional application No. 63/553,107, filed on Feb. 13, 2024.

(51) Int. Cl. G01R 31/319; G01R 31/317; H03M 1/12

(52) U.S. Cl. CPC G01R 31/31926; G01R 31/31703; H03M 1/12

(57) ABSTRACT

A test and measurement instrument to receive a signal from a device under test, one or more analog-to-digital converters to receive the signal and convert the signal to digital samples, a moving max filter to receive the digital samples and produce a max value waveform from the digital samples within an envelope width to trigger operation of the test and measurement instrument, and one or more buffers to store max values from the digital samples. A moving max filter includes a max build-up circuit connected to one or more buffers to produce a building_up_max value, a max build-down circuit connected to the one or more buffers to determine which stored max values can be cleared from the one or more buffers and produce a building_down_max value, and a comparison block to find a maximum between the building_up_max value and the building_down_max value and to output the maximum.

### CROSS-REFERENCE TO RELATED APPLICATIONS

This disclosure is a non-provisional of and claims benefit from U.S. Provisional Application No. 63/553,107, titled “MOVING MAX ENVELOPE FILTER,” filed on Feb. 13, 2024, the disclosure of which is incorporated herein by reference in its entirety.

### TECHNICAL FIELD

This disclosure relates to test and measurement instruments, and more particularly to envelope filters used in test and measurement instruments.

### BACKGROUND

Envelope filters, sometimes also referred to as envelope detectors, generally create a voltage based upon the signal's amplitude fluctuations. This may allow a device to operate on the signal based upon the signal's amplitude. The instrument may use this type of filter to demodulate amplitude modulated (AM) signals, or for operations that trigger or start based upon the incoming values having a particular value compared to other values in the signal. FIG. 1 shows an ideal envelope filter waveform, with the incoming signal 10 and the resulting envelope 12.

Currently, these filters are typically implemented as analog circuitry. This circuitry may comprise a diode, resistance, and capacitance. FIG. 2 shows an example of an analog envelope filter 14. Diode 16 receives the incoming analog signal from a device under test, with a resistor 18 and a capacitor 20. Diode 16 acts as a rectifier and only conducts during positive half-cycles of the signal, creating a series of pulses corresponding to the signal envelope. Capacitor 20 charges up as the incoming voltage reaches peaks then the resistor 18 discharges the capacitor.

FIG. 3 shows an example of an analog envelope waveform 22 derived from an input signal 24. Smoothing out the resulting waveform to have a max value pulse of some duration would improve instrument operations.

### BRIEF DESCRIPTION OF THE DRAWINGS

FIG. 1 shows an example of an ideal envelope waveform.

FIG. 2 shows an example of an analog envelope filter.

FIG. 3 shows an example of an analog envelope waveform.

FIG. 4 shows an embodiment of a moving max filter as an envelope filter.

FIG. 5 shows a stretched max filter waveform.

FIG. 6 shows an example of sample grouping for a moving max envelope filter width of 18 samples.

FIG. 7 shows an embodiment of a max build-up portion of a moving max filter.

FIG. 8 shows an embodiment of a build-down portion of a moving max filter.

FIG. 9 shows an embodiment of a rising edge delay circuit portion of a moving max filter.

FIG. 10 shows an example of a delayed max waveform.

FIG. 11 shows an example of a delayed rise edge output waveform.

FIGS. 12A-12D show examples of moving max envelope filter waveforms.

FIG. 13 shows an example of an envelope with differential moving max.

FIG. 14 shows an example of a max envelope filter for an RF envelope with common mode decay.

FIGS. 15A-15D show different examples of waveforms with common mode decay.

FIG. 16 shows an example of a max envelope filter for an RF envelope with floor ceiling decay.

FIGS. 17A-17D show examples of waveforms with floor ceiling decay.

FIG. 18 shows an embodiment of a filter for an RF envelope with constant decay.

FIG. 19A-19D show examples of RF waveforms with constant decay.

FIG. 20 shows an embodiment of a filter for an RF envelope with peak and flat detects.

FIGS. 21A-21D show examples of RF waveforms with peak and flat detects.

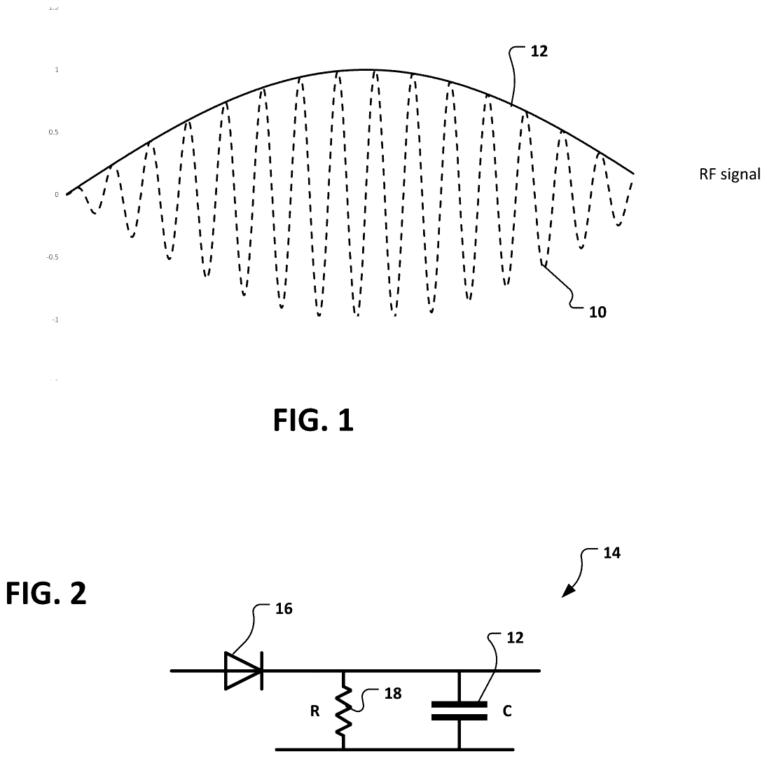

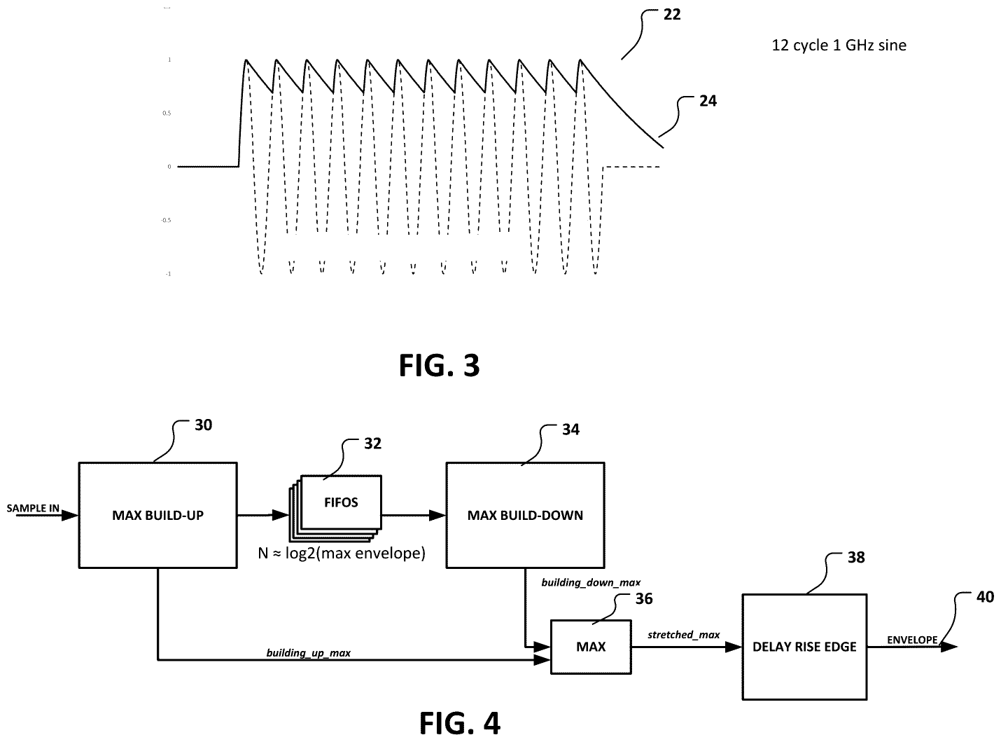

### DESCRIPTION

The embodiments here involve using a moving max filter as an envelope filter in a test and measurement instrument, such as an oscilloscope, for example. The envelope filter detects the rising edge of a signal, such as a radio frequency (RF) signal. Test and measurement instruments generally require a trigger or other signal that causes the instrument to start operating on samples of an incoming signal. The operations may include acquiring the samples of a waveform and storing them for analysis of a device under test (DUT) that produces the signal. For purposes of this discussion, the term “trigger” means any event or signal that causes the instrument to perform operations on the incoming data.

Generally, the samples result from an incoming signal from a DUT. One or more analog-to-digital converters (ADC) take the incoming signal and convert it into a series of digital samples. The moving max filter passes the max value of a window of samples, referred to here as an “envelope.” The envelope width is selectable, usually during operation of the test and measurement instrument (“instrument”). The user may select the envelope width prior to starting the signal reception at the instrument. This will determine the length of time that corresponds to the number of samples in the envelope. The output of the process is a stable value between two pulses that occur within the period of time at the lower max value of the two pulses.

The embodiments may also output a differential signal, by pairing the moving max filter with a moving min filter to provide a differential output as the trigger. No limitation to single-ended or differential signals is intended nor should any be inferred.

The embodiments also provide an ability to switch between moving max filter, and latched value to better represent an envelope filter by delaying rising edges. Rising edges may trigger the instrument so controlling the timing of their occurrence provides control of when the instrument begins to operate on the samples.

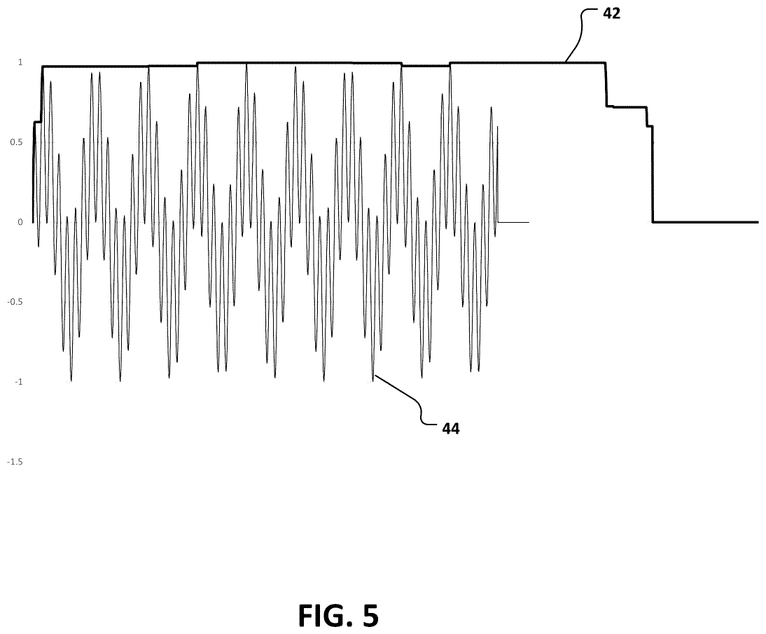

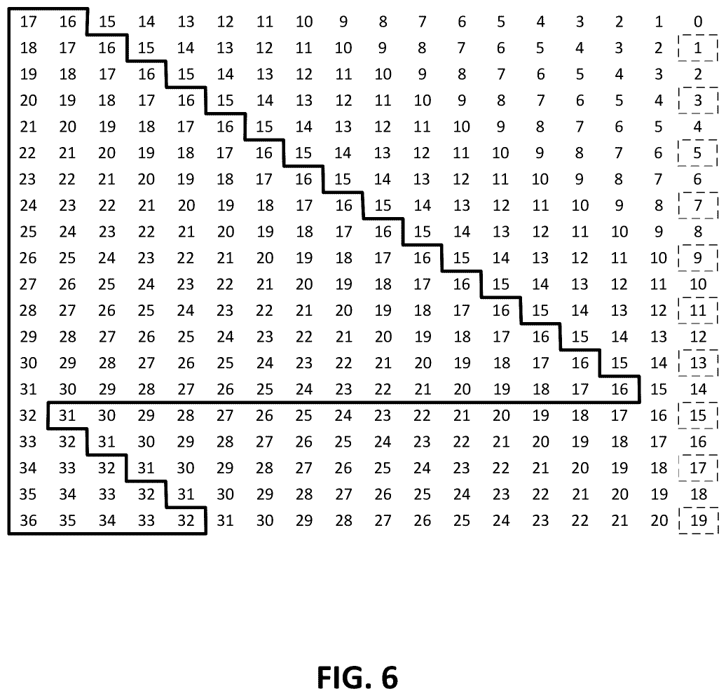

FIG. 4 shows an embodiment of a moving max filter usable to replace the analog envelope filters typically deployed in test and measurement instruments. The max build-up block 30 receives an incoming digital sample, which this discussion may also refer to as the current digital sample. The max build-up block 30 or circuit determines and groups max values for incoming values. The max values groups are stored in one or more buffers 32, in one embodiment these buffers comprise first-in-first-out (FIFO) buffers, discussed in more detail regarding FIG. 6. The max build-down block or circuit 34 determines which of the max values is in the envelope window not covered by the building_up_max value by using some of the stored max values.

The MAX block 36 allows the max value filter to select the higher value between the building_up_max value and the building_down_max value. The max value may be referred to as a “stretched” max value, which means that the max value will repeat for a number of sample times corresponding to a desired pulse width, possibly equal to the envelope width, making the output a wider pulse with one value. FIG. 5 shows an example of a stretched max waveform 42 resulting from the input sample waveform 44. One should note that the output of the MAX block 36 comprises the moving max filter output and can be used for the max value waveform. The Delay Rise Edge block 38 discussed in more detail below provides an idealized envelope, referred to as the max envelope filter output. The max value waveform may result from either the moving max filter output or the max envelope filter output.

FIG. 6 shows an example of how max values are grouped and used for envelope length of 18 samples. Each column corresponds to the samples used for the envelope output for each clock cycle. The numbers inside the heavy black line are the samples used for determining the building_up_max value. Once the building_up_max value consists of 16 samples, it gets passed to the max build-down block 34 through a FIFO in the set of FIFOs 32 and building_up_max goes back to consisting of 1 value. The numbers on the right in the dashed boxes are the single values passed from max build-up 30 to max build-down 34 through a FIFO. Other groupings of samples consist of powers of 2 groupings passed between the blocks.

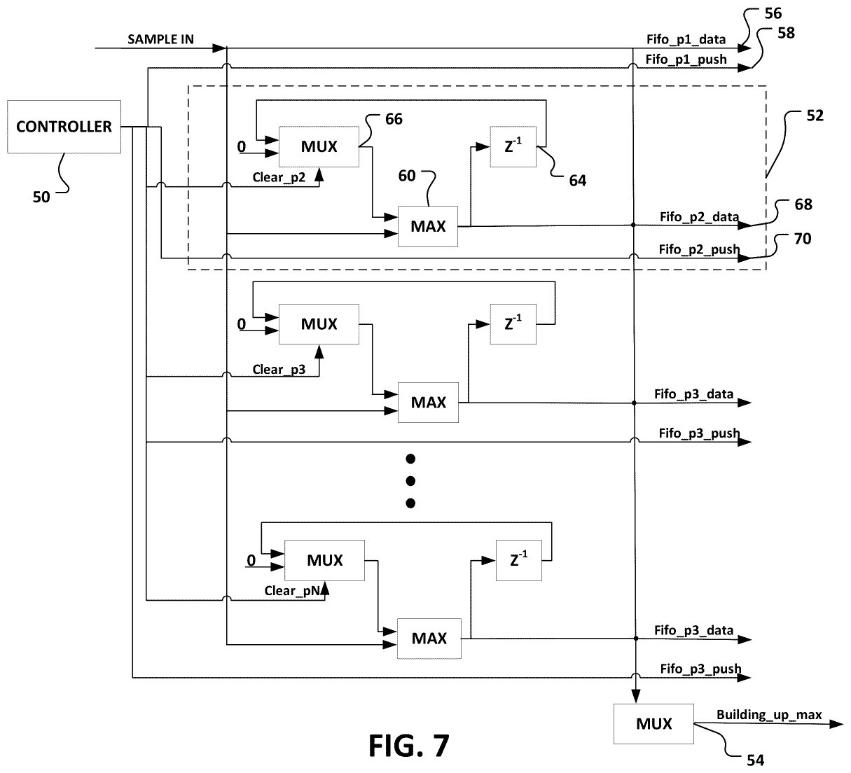

FIG. 7 shows an embodiment of a max build up block 30 from FIG. 4. The incoming sample goes to each max filter group of the overall build up block. A filter group is shown in the dashed box 52. The filter group includes a MAX circuit 60 that compares an incoming sample to the previous sample, illustrated as delay block Z⁻¹. In one embodiment, the previous sample is stored in a register. The previous sample stored in a buffer 64 and then pulled by the multiplexer (MUX) 66, and then could send to it to the MAX circuit. The MUX receives a clear signal that tells the MUX to use 0, or the lowest possible value, to restart the building up max process. The resulting max value would then be pushed to a corresponding FIFO or other buffer based upon the signal Fifo_p2_push. To reduce hardware needed to implement the max build-up block, each filter group handles a different number of samples by powers of 2. The incoming sample would be pushed to the FIFO based upon the Fifo_p1_push signal, with no comparison. This represents 2⁰, or 1 sample. Filter group p2 is 2¹, or 2 samples, group p3 has 4 samples, group p4 would have 8 samples, etc., until pN, which represents whatever number of samples determined by the designer. The MUX 54 at the bottom sends the max value of one of the filter groups as the building_up_max output determined by the controller. The controller 50 provides the control signals to the MUXes, and the FIFOs.

Table 1 shows example control values. In the control values, at time 1, the values for FIFO push for p2, p3, p4, and p5 are all zero, as they are skipped at startup. At this point, the circuit has created enough samples to create a correct output. The p5 group is operating all the time because its value is being used for building_up_max in this example. The max values are stored in the Z⁻¹ registers, meaning that the sample has been stored in the register for one clock cycle. The controller selects p5 because at 16 samples it is the close to the envelope size without exceeding it.

TABLE 1

| Control Values for Envelope Width of 18 | | | | | | | | | | N Build- |
|---|---|---|---|---|---|---|---|---|---|---|
| FIFO Push | | | | | | Max Clear | | | | up |
| Time | p1 | p2 | p3 | p4 | p5 | p2 | p3 | p4 | p5 | Samples |
| 0 | 0 | 0 | 0 | 0 | 0 | — | — | — | 1 | — |
| 1 | 1 | 0 | 0 | 0 | 0 | — | — | — | 0 | — |
| 2 | 0 | 0 | 0 | 0 | 0 | 1 | — | — | 0 | — |
| 3 | 1 | 1 | 0 | 0 | 0 | 0 | — | — | 0 | — |
| 4 | 0 | 0 | 0 | 0 | 0 | — | 1 | — | 0 | |
| 5 | 1 | 0 | 0 | 0 | 0 | — | 0 | — | 0 | |
| 6 | 0 | 0 | 0 | 0 | 0 | 1 | 0 | — | 0 | |
| 7 | 1 | 1 | 1 | 0 | 0 | 0 | 0 | — | 0 | |
| 8 | 0 | 0 | 0 | 0 | 0 | — | — | 1 | 0 | |
| 9 | 1 | 0 | 0 | 0 | 0 | — | — | 0 | 0 | |
| 10 | 0 | 0 | 0 | 0 | 0 | 1 | — | 0 | 0 | |
| 11 | 1 | 1 | 0 | 0 | 0 | 0 | — | 0 | 0 | |
| 12 | 0 | 0 | 0 | 0 | 0 | — | 1 | 0 | 0 | |
| 13 | 1 | 0 | 0 | 0 | 0 | — | 0 | 0 | 0 | |
| 14 | 0 | 0 | 0 | 0 | 0 | 1 | 0 | 0 | 0 | |
| 15 | 1 | 1 | 1 | 1 | 1 | 0 | 0 | 0 | 0 | |
| 16 | 0 | 0 | 0 | 0 | 0 | — | — | — | 1 | |
| 17 | 1 | 0 | 0 | 0 | 0 | — | — | — | 0 | 2 |
| 18 | 0 | 0 | 0 | 0 | 0 | 1 | — | — | 0 | 3 |
| 19 | 1 | 1 | 0 | 0 | 0 | 0 | — | — | 0 | 4 |
| 20 | 0 | 0 | 0 | 0 | 0 | — | 1 | — | 0 | 5 |
| 21 | 1 | 0 | 0 | 0 | 0 | — | 0 | — | 0 | 6 |
| 22 | 0 | 0 | 0 | 0 | 0 | 1 | 0 | — | 0 | 7 |
| 23 | 1 | 1 | 1 | 0 | 0 | 0 | 0 | — | 0 | 8 |
| 24 | 0 | 0 | 0 | 0 | 0 | — | — | 1 | 0 | 9 |
| 25 | 1 | 0 | 0 | 0 | 0 | — | — | 0 | 0 | 10 |
| 26 | 0 | 0 | 0 | 0 | 0 | 1 | — | 0 | 0 | 11 |
| 27 | 1 | 1 | 0 | 0 | 0 | 0 | — | 0 | 0 | 12 |
| 28 | 0 | 0 | 0 | 0 | 0 | — | 1 | 0 | 0 | 13 |
| 29 | 1 | 0 | 0 | 0 | 0 | — | 0 | 0 | 0 | 14 |
| 30 | 0 | 0 | 0 | 0 | 0 | 1 | 0 | 0 | 0 | 15 |
| 31 | 1 | 1 | 1 | 1 | 1 | 0 | 0 | 0 | 0 | 16 |
| 32 | 0 | 0 | 0 | 0 | 0 | — | — | — | 1 | 1 |
| 33 | 1 | 0 | 0 | 0 | 0 | — | — | — | 0 | 2 |

For other envelope widths, other combinations of the filter groups would be used. For example, for an envelope width of 15, the following times for building up samples and building down FIFOs would be as follows: 1: p4, p3, p2 (1+8+4+2=15); 2: p4, p3, p1 (2+8+4+1=15); 3: p4, p3 (3+8+4=15); 4: p4, p2, p1 (4+8+2+1=15); 5: p4, p2 (5+8+2=15); 6: p4, p1 (6+8+1=15); 7: p4 (7+8=15); 8: p3, p2, p1 (8+4+2+1=15).

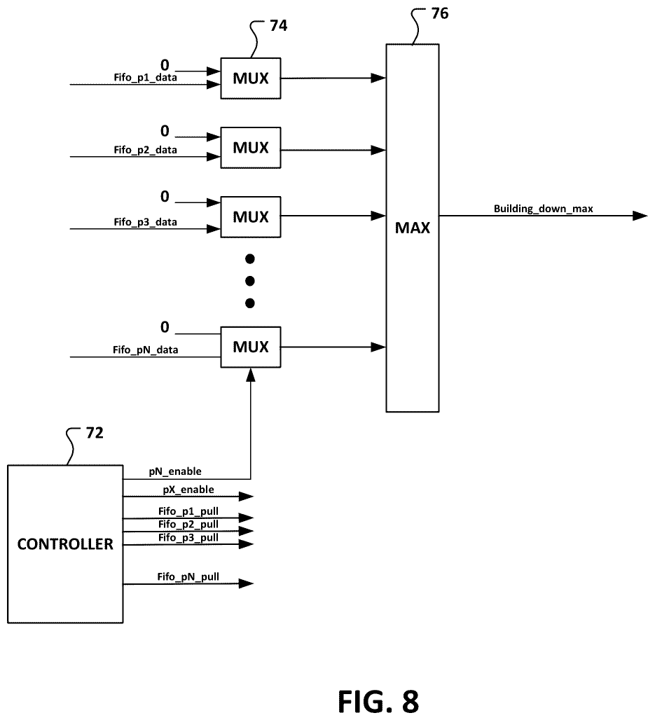

Returning to FIG. 4, once the building_up_max value for the last N samples is determined, in this embodiment 16 samples, the max value is sent to the max build-down block 36 through the FIFOs. FIG. 8 shows an embodiment of a max build-down block. The controller 72 may be a separate controller than the controller 50 of FIG. 7. In one embodiment, the two controllers comprise sections or blocks of an FPGA (field-programmable gate array), or an ASIC (Application Specific Integrated Circuit). In either case, the controller outputs an enable signal pX_enable, where the X is whatever filter group's MUX such as 74 for p1 is being enabled, such as p2, p3, etc. pN_enable represents the signal for the MUX corresponding to the last filter group. As each value from each MUX comes into the MAX block 76, the MAX block determines the max value until all the max values of all the filter group MUX outputs have been processed. The resulting building_down_max value comprises the highest value of all the values processed. Table 2 shows the various control signal values to operate the building down block.

TABLE 2
Control Values for Envelope Width of 18

| FIFO Pull | | | | | | Data Enable | | | | |
|---|---|---|---|---|---|---|---|---|---|---|
| Time | p1 | p2 | p3 | p4 | p5 | p1 | p2 | p3 | p4 | p5 |
| 17 | 0 | 0 | 0 | 0 | 1 | 0 | 0 | 0 | 0 | 1 |
| 18 | 1 | 1 | 1 | 1 | 0 | 1 | 1 | 1 | 1 | 0 |
| 19 | 0 | 0 | 0 | 0 | 0 | 0 | 1 | 1 | 1 | 0 |
| 20 | 1 | 0 | 0 | 0 | 0 | 1 | 0 | 1 | 1 | 0 |
| 21 | 0 | 0 | 0 | 0 | 0 | 0 | 0 | 1 | 1 | 0 |
| 22 | 1 | 1 | 0 | 0 | 0 | 1 | 1 | 0 | 1 | 0 |
| 23 | 0 | 0 | 0 | 0 | 0 | 0 | 1 | 0 | 1 | 0 |
| 24 | 1 | 0 | 0 | 0 | 0 | 1 | 0 | 0 | 1 | 0 |
| 25 | 0 | 0 | 0 | 0 | 0 | 0 | 0 | 0 | 1 | 0 |
| 26 | 1 | 1 | 1 | 0 | 0 | 1 | 1 | 1 | 0 | 0 |
| 27 | 0 | 0 | 0 | 0 | 0 | 0 | 1 | 1 | 0 | 0 |
| 28 | 1 | 0 | 0 | 0 | 0 | 1 | 0 | 1 | 0 | 0 |
| 29 | 0 | 0 | 0 | 0 | 0 | 0 | 0 | 1 | 0 | 0 |
| 30 | 1 | 1 | 0 | 0 | 0 | 1 | 1 | 0 | 0 | 0 |
| 31 | 0 | 0 | 0 | 0 | 0 | 0 | 1 | 0 | 0 | 0 |
| 32 | 1 | 0 | 0 | 0 | 0 | 1 | 0 | 0 | 0 | 1 |
| 33 | 0 | 0 | 0 | 0 | 0 | 0 | 0 | 0 | 0 | 1 |
| 34 | 1 | 1 | 1 | 1 | 0 | 1 | 1 | 1 | 1 | 0 |
| 35 | 0 | 0 | 0 | 0 | 0 | 0 | 1 | 1 | 1 | 0 |
| 36 | 1 | 0 | 0 | 0 | 0 | 1 | 0 | 1 | 1 | 0 |
| 37 | 0 | 0 | 0 | 0 | 0 | 0 | 0 | 1 | 1 | 0 |
| 38 | 1 | 1 | 0 | 0 | 0 | 1 | 1 | 0 | 1 | 0 |
| 39 | 0 | 0 | 0 | 0 | 0 | 0 | 1 | 0 | 1 | 0 |
| 40 | 1 | 0 | 0 | 0 | 0 | 1 | 0 | 0 | 1 | 0 |

The building_up_max value is also sent to MAX block 36 of FIG. 4. An embodiment of a max build-down block is shown in FIG. 8. The MAX block 36 determines the max value between the building_up_max and the building_down_max. The discussion refers to the resulting value as the “stretched max.” This value is “stretched” as the output value for the envelope width.

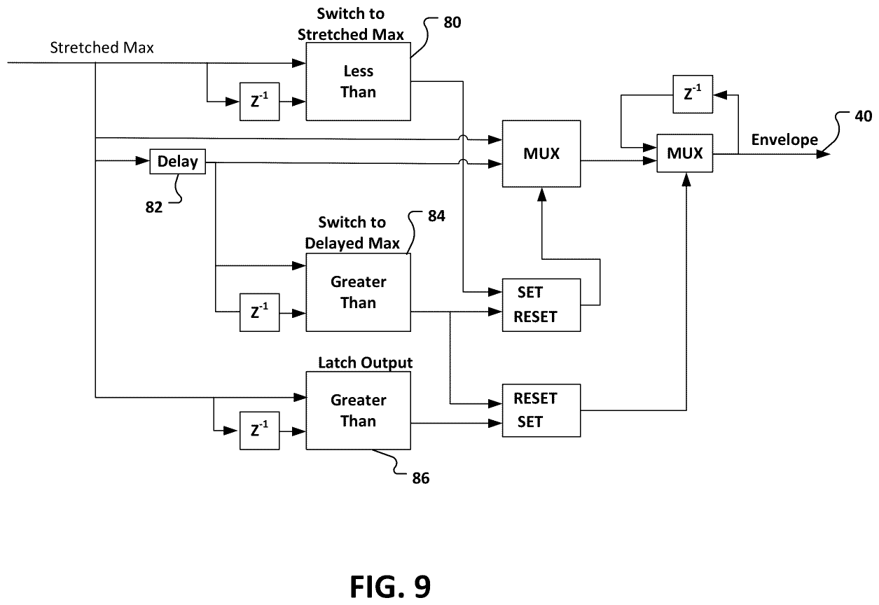

FIG. 9 shows an embodiment of a Delay Rise Edge block 38 from FIG. 4. The delay rise edge block has three states. It does one of output stretched_max, output delayed_max and does not change output. Generally, the flow is that the Delay Rise Edge block switches output to stretched_max when stretched_max goes down, meaning that stretched_max value no longer represents the max value. When the stretched_max goes up, the output is held. Finally, if delayed_max rises, making it the max value, the output switches to delayed_max.

In FIG. 9, the stretched_max signal comes into the max build-down block. The stretched_max signal is compared to the previous value, Z⁻¹, at 80. At 80, if the stretched_max is less than the previous stretched_max signal, the output switches to the current stretched_max. At 82, a delayed version of the stretched_max signal is created that is delayed by the envelope width. At 84, If the value of delayed_value is greater than the previous delayed_value, the output will become the delayed_value. At 86 the stretched_max signal is compared to the previous value stretched_max signal, and if the current stretched_max is greater, the output is latched, until another increase in the delayed_value is detected at 84.

The stretched_max output may comprise the moving max filter output and the output resulting from the delayed rising edge the moving max envelope filter output. The moving max envelope filter output that results from the delay rising edge block produces a more idealized envelope. The moving max filter output is usable on its own, but the delay rise edge block results in an idealized envelope.

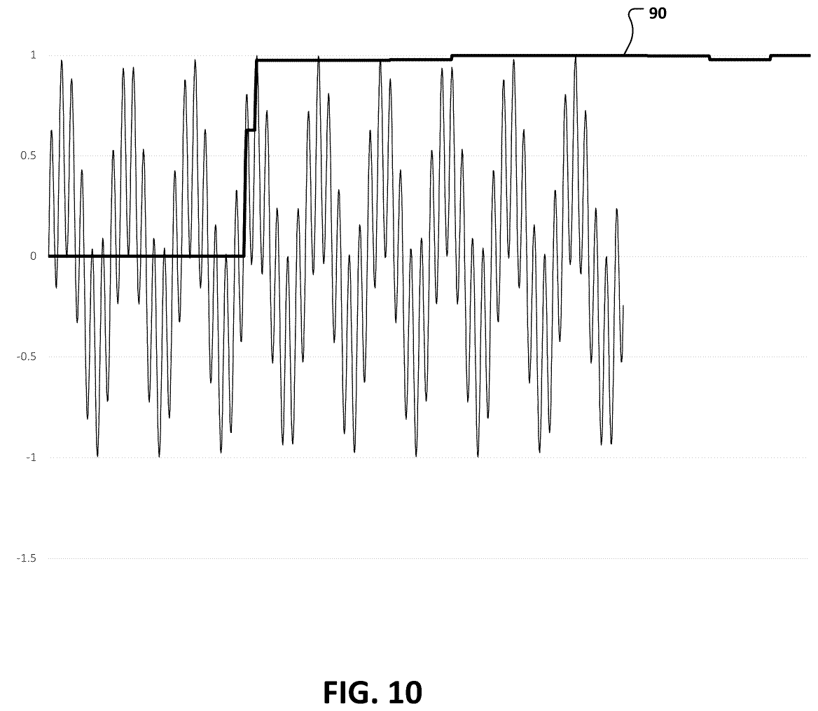

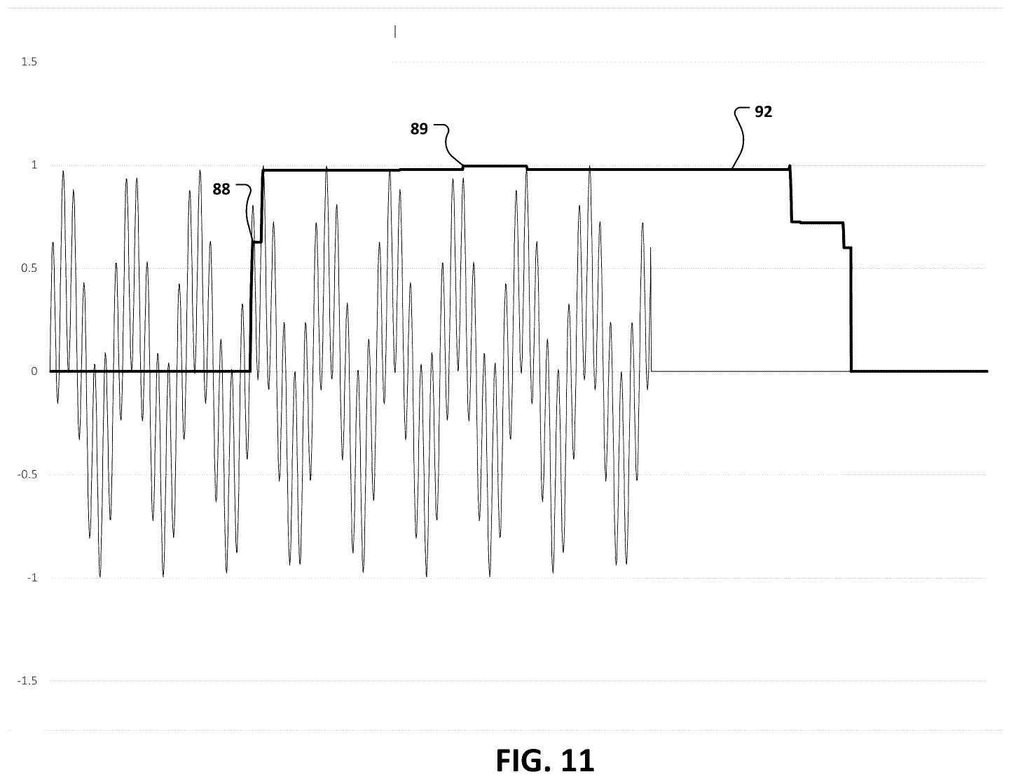

FIG. 10 shows an example output waveform 90 corresponding to the output of the delayed rise edge block 40 of FIG. 4 if it is a delayed moving max from 82. FIG. 11 shows an example output 92 if the envelope is a moving max for a two-tone waveform. The different changes, such as those shown by 88 and 89, are when the output value changes based on switching between the different outputs discussed in FIG. 9. Any rising edges such as 88 and 89 result from the delayed max value. Falling edges result from the stretched_max.

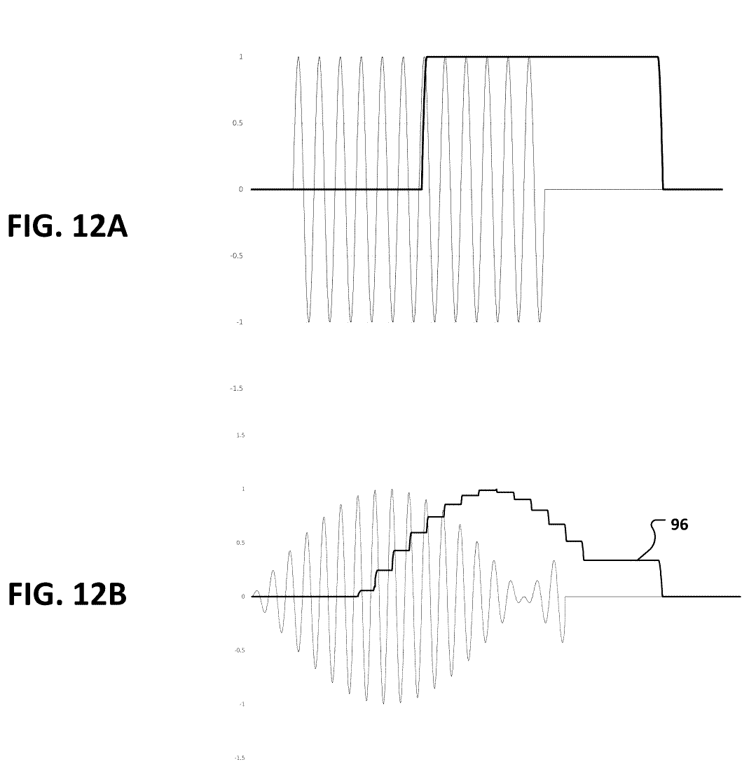

FIGS. 12A-12D show other examples of moving max envelope waveforms, 94 for a 12 cycle, 1 GHz sine wave, 96 a 62.5 MHz*1 GHz signal, 98 a 62.5 MHz*20.83 GHz signal, and 100 for serial data.

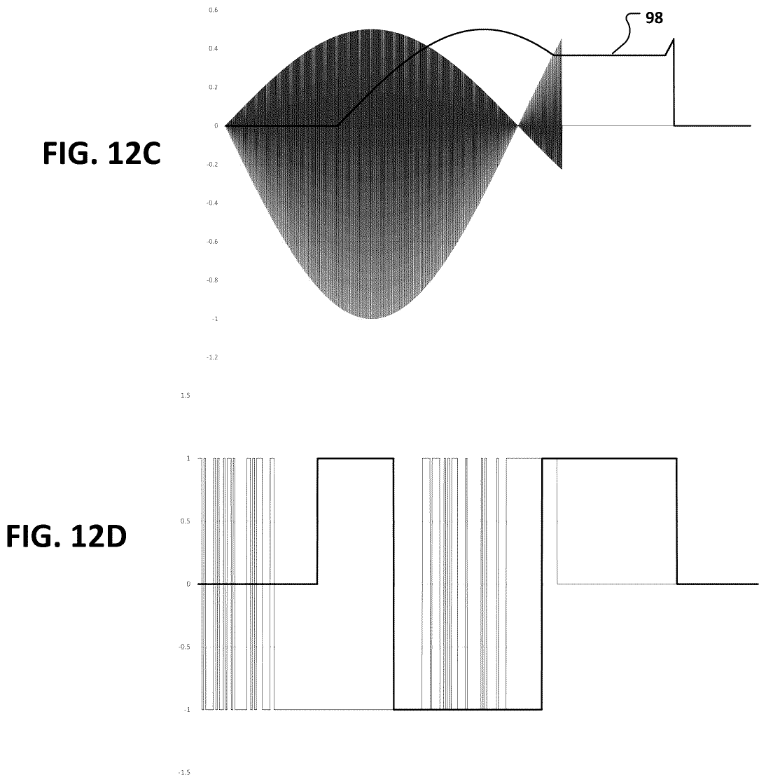

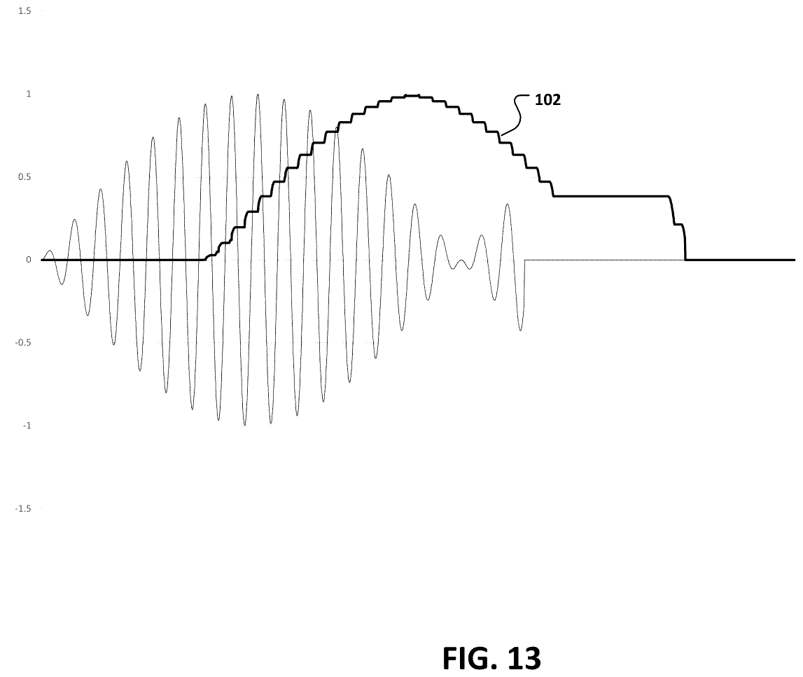

The above discussion focuses on a single output value, such as for a singled-ended output. However, one could implement a min max filter with a corresponding structure but instead of tracking the maximum values, it tracks minimum values. This would allow an output showing the difference between the maximum and minimum filter outputs. FIG. 13 shows an example of a differential moving max envelope with output 102.

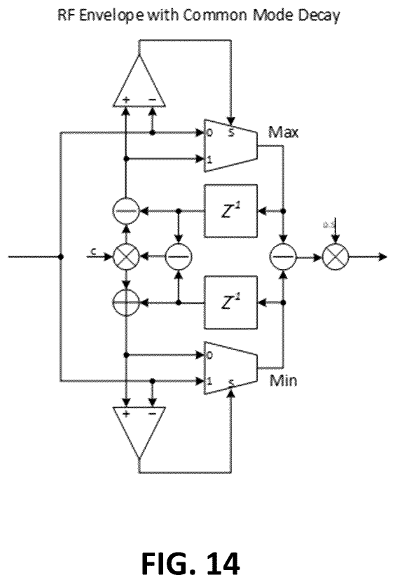

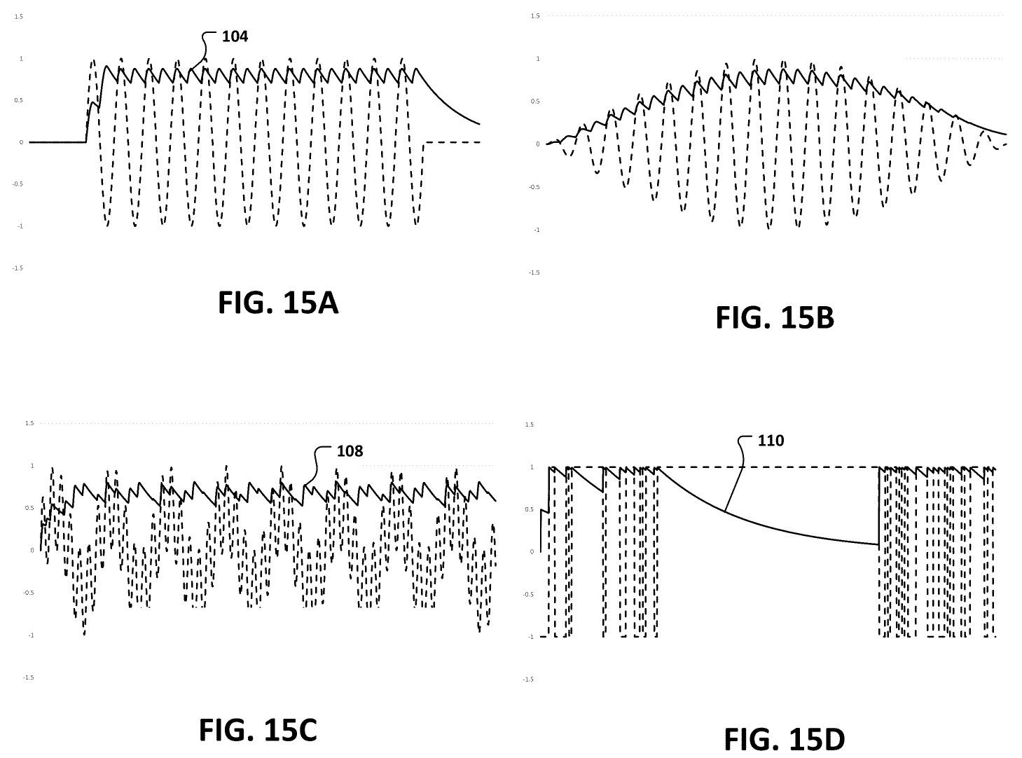

FIG. 14 through FIG. 21D show other examples of RF envelope circuits. FIG. 14 shows an example of an envelope circuit for signals with common mode decay in which minimum and maximum envelope values with decay towards each other. FIGS. 15A-15D illustrate the resulting envelope signals, 104, 106, 108, and 110, when different input signals are processed by the envelope filter of FIG. 14.

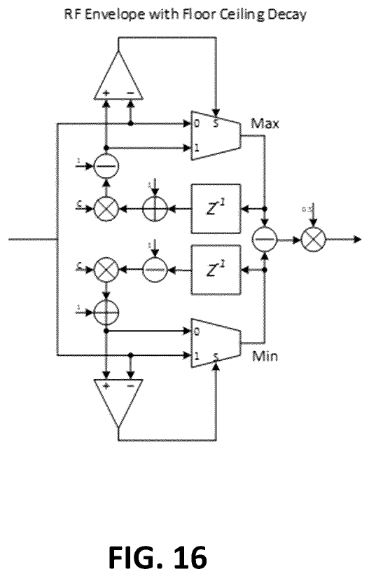

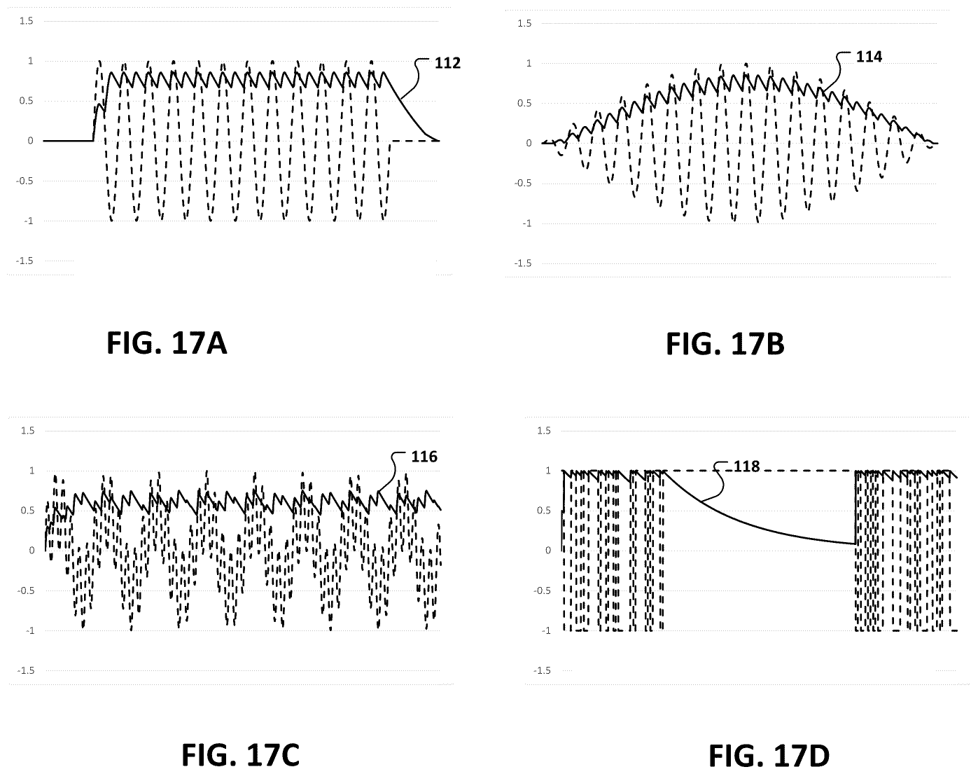

FIG. 16 shows an example of an RF envelope filter with Floor Ceiling Decay in which minimum values decay towards the top of the figure, and maximum values decay towards the bottom of the figure. FIGS. 17A-17D illustrate the resulting envelope signals, 112, 114, 116, and 118.

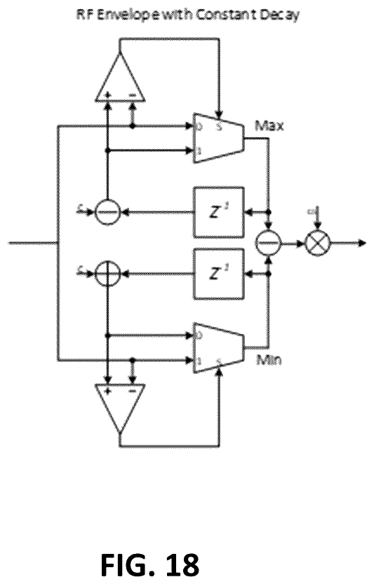

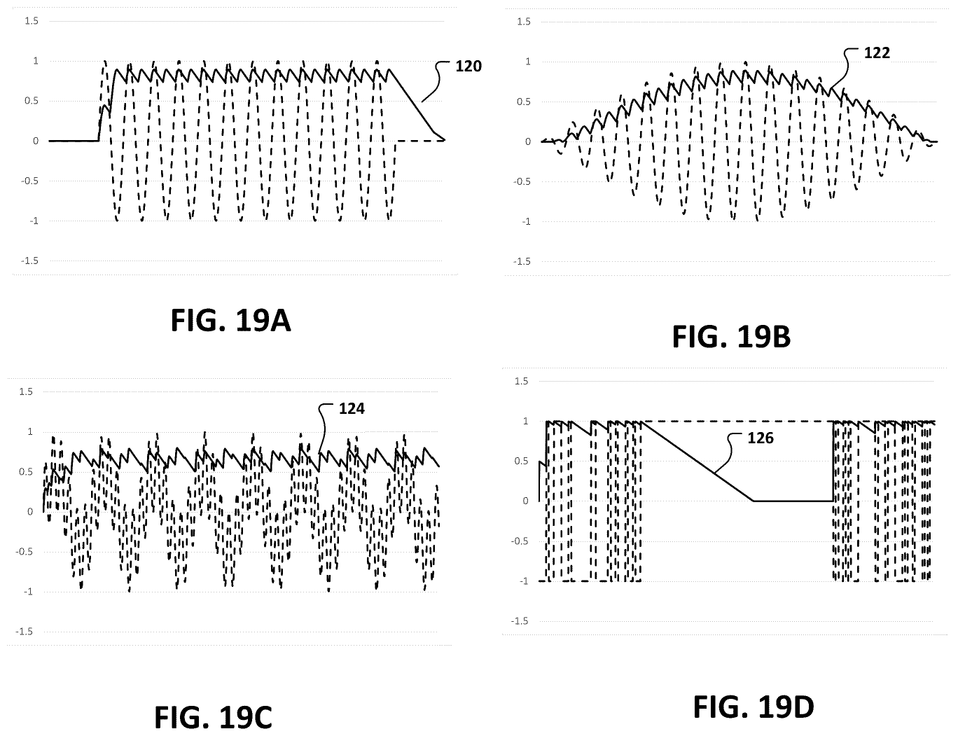

FIG. 18 shows an example RF envelope filter with Constant Decay envelope filter, where constant decay means the minimum value constantly increases and the maximum value constantly decreases. FIGS. 19A-19D illustrate the resulting envelope signals 120, 122, 124, and 126, when different input signals are processed by the envelope filter of FIG. 18.

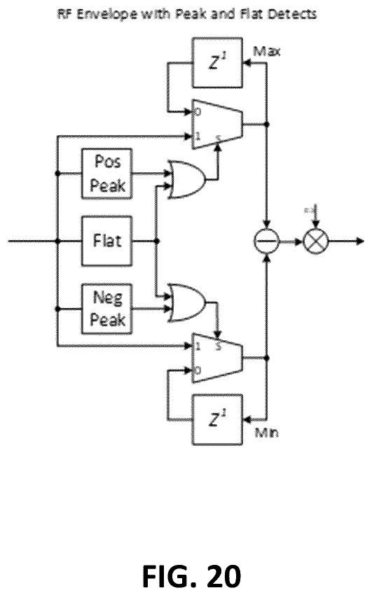

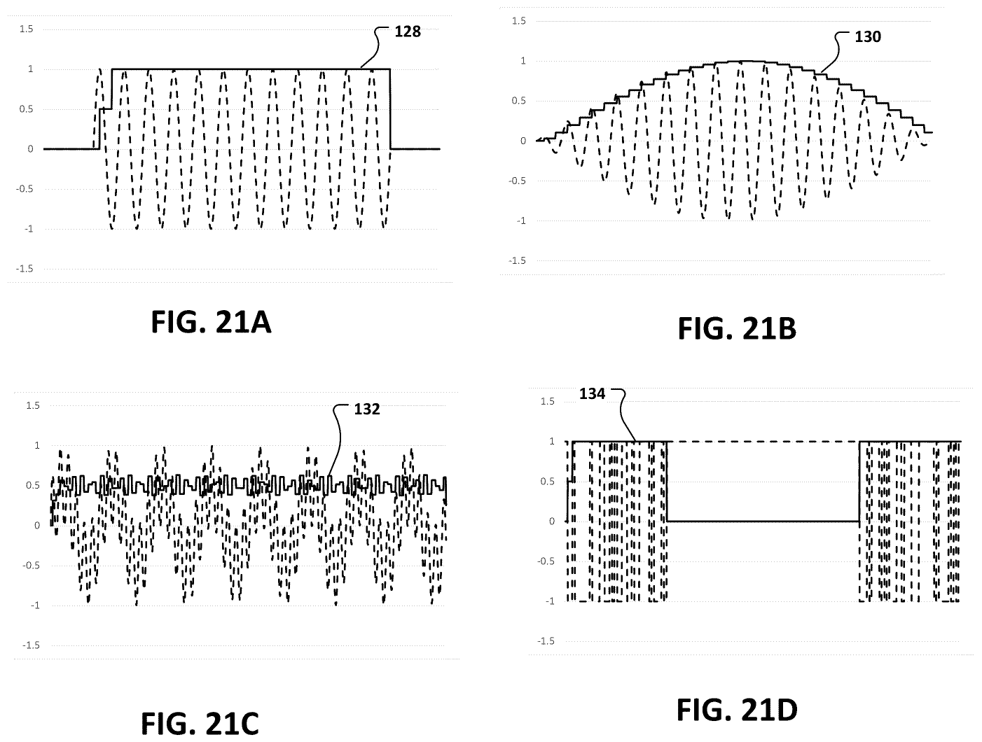

FIG. 20 shows an RF envelope filter with Peak and Flat Detects envelope filter. FIGS. 21A-21D illustrate the resulting envelope signals 128, 130, 132, and 134, when different input signals are processed by the envelope filter of FIG. 20.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Example 1 is a test and measurement instrument, comprising: one or more ports to receive a signal from a device under test (DUT); one or more analog-to-digital converters (ADC) to receive the signal and convert the signal to digital samples; a moving max filter to receive the digital signals and produce a max value waveform based upon max values from the digital samples within an envelope width to be used to trigger operation of the test and measurement instrument; and one or more buffers to store max values from the digital samples.

Example 2 is the test and measurement instrument of Example 1, wherein the moving max filter comprises: a max build-up circuit connected to the one or more buffers to produce a building_up_max value; a max build-down circuit connected to the one or more buffers to determine which stored max values can be used from the one or more buffers and produce a max building_down_max value as max value; and a max comparison block to compare the building_up_max value and the building_down_max value and output a moving maximum filter output as the max value waveform.

Example 3 is the test and measurement instrument of Example 2, wherein the max build-down circuit comprises: one or more multiplexers corresponding to a number of the one or more buffers; a controller to provide control signals to the one or multiplexers; and a max comparison circuit to produce the building_down_max value.

Example 4 is the test and measurement instrument of Example 2, wherein the max build-up circuit comprises a controller, an output multiplexer, and one or more filter groups, each filter group comprising: a max comparison circuit to compare a current sample with a previous sample to determine a max sample, the max comparison circuit connected to the one or more buffers and the output multiplexer; a store to store the max sample connected to the max comparison circuit for a next comparison; and a group multiplexer connected to the store to send the max sample to the max comparison circuit.

Example 5 is the test and measurement instrument of Example 4, wherein the one or more filter groups each operate on a number of samples in powers of two.

Example 6 is the test and measurement instrument of Example 4, wherein the groups selected by the controller to send data to the output multiplexer is determined by the envelope width.

Example 7 is the test and measurement instrument of Example 2, further comprising a delay rise edge block connected to the max build-up circuit and the max build-down circuit to receive the moving maximum filter output to produce a max envelope filter output as the max value waveform output.

Example 8 is the test and measurement instrument of Example 7, wherein the delay rise edge block comprises: a delay to receive the moving max filter value and produce a delayed value; one or more comparison blocks to determine whether to select the building_up_max value, the delayed value, or to hold the output value to a most recent value as the max value; and a multiplexer to output the max value for an envelope width to produce a max envelope filter output as the max value waveform.

Example 9 is the test and measurement instrument of any of Examples 1 through 8, wherein the buffers comprise first-in-first-out buffers (FIFOs) connected to the controller.

Example 10 is the test and measurement instrument of any of Examples 1 through 9, further comprising: a moving min filter to receive the digital signals and produce a min value based upon min values from the digital samples within an envelope width; and a circuit to combine the max value waveform and the min value as a differential input to be used to trigger operation of the test and measurement instrument.

Example 11 is the test and measurement instrument of any of Examples 1 through 10, wherein the test and measurement instrument comprises an oscilloscope.

Example 12 is a moving max filter comprising: a max build-up circuit connected to one or more buffers to produce a building_up_max value; a max build-down circuit connected to the one or more buffers to determine which stored max values can be cleared from the one or more buffers and produce a building_down_max value; and a comparison block to find a maximum between the building_up_max value and the building_down_max value and to output the maximum as a moving max filter output.

Example 13 is the moving max filter of Example 12, further comprising a delay rise edge block connected to the comparison block to select the maximum envelope filter output as a maximum value waveform.

Example 14 is the filter of Example 13, wherein the delay rise edge block comprises: a delay to receive the moving max filter output and produce a delayed value; one or more comparison blocks to determine whether to select the building_up_max value, the delayed value, or to hold the output value to a most recent value as the max value; and a multiplexer to output the max value for an envelope width to produce a maximum envelope filter output as a max value waveform.

Example 15 is the filter of an of Examples 12 through 14, wherein the max build-up circuit comprises a controller, an output multiplexer, and one or more filter groups, each filter group comprising: a max comparison circuit to compare a current sample with a previous sample to determine a max sample, the max comparison circuit connected to the one or more buffers and the output multiplexer; a store to store the max sample connected to the max comparison circuit for a next comparison; and a group multiplexer connected to the store to send the max sample to the max comparison circuit.

Example 16 is the filter of Example 15, wherein the one or more filter groups each operate on a number of samples in powers of two.

Example 17 is the filter of Example 15, wherein the groups selected by the controller to send data to the output multiplexer are determined by the envelope width.

Example 18 is the filter of any of Examples 12 through 17, wherein the max build-down circuit comprises: one or more multiplexers corresponding to a number of the one or more buffers; a controller to provide control signals to the one or multiplexers and buffers; and a max comparison circuit to produce the building_down_max value.

Example 19 is the filter of any of Examples 12 through 18, wherein the buffers comprise first-in-first-out buffers (FIFOs) connected to the controller.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement instrument, comprising:
one or more ports to receive a signal from a device under test (DUT);
one or more analog-to-digital converters (ADC) to receive the signal and convert the signal to digital samples;
a moving max filter to receive the digital samples and produce a max value waveform based upon max values from the digital samples within an envelope width to be used to trigger operation of the test and measurement instrument; and
one or more buffers to store max values from the digital samples.

2. The test and measurement instrument as claimed in claim 1, wherein the moving max filter comprises:
a max build-up circuit connected to the one or more buffers to produce a building_up_max value;
a max build-down circuit connected to the one or more buffers to determine which stored max values can be used from the one or more buffers and produce a max building_down_max value as max value; and
a max comparison block to compare the building_up_max value and the building_down_max value and output a moving maximum filter output as the max value waveform.

3. The test and measurement instrument as claimed in claim 2, wherein the max build-down circuit comprises:
one or more multiplexers corresponding to a number of the one or more buffers;
a controller to provide control signals to the one or multiplexers; and
a max comparison circuit to produce the building_down_max value.

4. The test and measurement instrument as claimed in claim 2, wherein the max build-up circuit comprises a controller, an output multiplexer, and one or more filter groups, each filter group comprising:
a max comparison circuit to compare a current sample with a previous sample to determine a max sample, the max comparison circuit connected to the one or more buffers and the output multiplexer;
a store to store the max sample connected to the max comparison circuit for a next comparison; and
a group multiplexer connected to the store to send the max sample to the max comparison circuit.

5. The test and measurement instrument as claimed in claim 4, wherein the one or more filter groups each operate on a number of samples in powers of two.

6. The test and measurement instrument as claimed in claim 4, wherein the groups selected by the controller to send data to the output multiplexer is determined by the envelope width.

7. The test and measurement instrument as claimed in claim 2, further comprising a delay rise edge block connected to the max build-up circuit and the max build-down circuit to receive the moving maximum filter output to produce a max envelope filter output as the max value waveform output.

8. The test and measurement instrument as claimed in claim 7, wherein the delay rise edge block comprises:
a delay to receive the moving max filter value and produce a delayed value;
one or more comparison blocks to determine whether to select the building_up_max value, the delayed value, or to hold the output value to a most recent value as the max value; and
a multiplexer to output the max value for an envelope width to produce a max envelope filter output as the max value waveform.

9. The test and measurement instrument as claimed in claim 1, wherein the buffers comprise first-in-first-out buffers (FIFOs) connected to the controller.

10. The test and measurement instrument as claimed in claim 1, further comprising:
a moving min filter to receive the digital signals and produce a min value based upon min values from the digital samples within an envelope width; and
a circuit to combine the max value waveform and the min value as a differential input to be used to trigger operation of the test and measurement instrument.

11. The test and measurement instrument as claimed in claim 1, wherein the test and measurement instrument comprises an oscilloscope.

12. A moving max filter comprising:
a max build-up circuit connected to one or more buffers to produce a building_up_max value;
a max build-down circuit connected to the one or more buffers to determine which stored max values can be cleared from the one or more buffers and produce a building_down_max value; and
a comparison block to find a maximum between the building_up_max value and the building_down_max value and to output the maximum as a moving max filter output.

13. The filter as claimed in claim 12, further comprising a delay rise edge block connected to the comparison block to select the maximum envelope filter output as a maximum value waveform.

14. The filter as claimed in claim 13, wherein the delay rise edge block comprises:
a delay to receive the moving max filter output and produce a delayed value;
one or more comparison blocks to determine whether to select the building_up_max value, the delayed value, or to hold the output value to a most recent value as the max value; and
a multiplexer to output the max value for an envelope width to produce a maximum envelope filter output as a max value waveform.

15. The filter as claimed in claim 12, wherein the max build-up circuit comprises a controller, an output multiplexer, and one or more filter groups, each filter group comprising:
a max comparison circuit to compare a current sample with a previous sample to determine a max sample, the max comparison circuit connected to the one or more buffers and the output multiplexer;
a store to store the max sample connected to the max comparison circuit for a next comparison; and
a group multiplexer connected to the store to send the max sample to the max comparison circuit.

16. The filter as claimed in claim 15, wherein the one or more filter groups each operate on a number of samples in powers of two.

17. The filter as claimed in claim 15, wherein the groups selected by the controller to send data to the output multiplexer are determined by the envelope width.

18. The filter as claimed in claim 12, wherein the max build-down circuit comprises:
one or more multiplexers corresponding to a number of the one or more buffers;
a controller to provide control signals to the one or multiplexers and buffers; and
a max comparison circuit to produce the building_down_max value.

19. The filter as claimed in claim 12, wherein the buffers comprise first-in-first-out buffers (FIFOs) connected to the controller.
